(19) United States
(12) Patent Application Publication
(10) Pub. No.: US 2026/0136590 A1
(43) Pub. Date: May 14, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Katsuhisa TANAKA, Himeji Hyogo (JP); Hiroshi KONO, Himeji Hyogo (JP)

(21) Appl. No.: 19/371,507

(22) Filed: Oct. 28, 2025

(30) Foreign Application Priority Data
Nov. 14, 2024 (JP) 2024-198788

(51) Int. Cl. H10D 30/66; H10D 62/10; H10D 62/832

(52) U.S. Cl. CPC H10D 30/665; H10D 30/668; H10D 62/107; H10D 62/109; H10D 62/8325

(57) ABSTRACT

A semiconductor device of an embodiment includes a device region and a termination region surrounding the device region. The device region includes first and second electrodes, a silicon carbide layer, and a gate electrode. The termination region includes the silicon carbide layer including: a first conductive type first silicon carbide region including a first region and a second region; a second conductive type fifth silicon carbide region on the second region; second conductive type sixth silicon carbide regions disposed in a first direction from the device region toward the termination region of the fifth silicon carbide region; a second conductive type seventh silicon carbide region between the first region and the second region; a second conductive type eighth silicon carbide region in the first direction of the seventh silicon carbide region; and second conductive type ninth silicon carbide region in the first direction of the sixth silicon carbide region.

### CROSS-REFERENCE TO RELATED APPLICATION

This application is based upon and claims the benefit of priority from Japanese Patent Application No. 2024-198788, filed on November 14, 2024, the entire contents of which are incorporated herein by reference.

### FIELD

Embodiments described herein relate generally to a semiconductor device.

### BACKGROUND

In a vertical metal oxide semiconductor field effect transistor using silicon carbide, for example, a termination region is provided around a device region including a transistor. The termination region relaxes the intensity of an electric field applied to a termination portion of a pn junction of the device region when the MOSFET is in an off state. The termination region has a function of improving a breakdown voltage of the MOSFET.

During operation of the MOSFET, for example, charge may be trapped in an insulating layer on the termination region. The charge is, for example, electrons or holes injected from the silicon carbide, or mobile ions entering from outside the MOSFET.

When charge is trapped in the insulating layer on the termination region, the electric field distribution in the termination region may change, and the breakdown voltage of the MOSFET may decrease. A decrease in the breakdown voltage of the MOSFET may reduce the reliability of the MOSFET.

### BRIEF DESCRIPTION OF THE DRAWINGS

FIG. 1 is a schematic top view of a semiconductor device of a first embodiment;

FIG. 2 is a schematic cross-sectional view of the semiconductor device of the first embodiment;

FIG. 3 is a schematic cross-sectional view of the semiconductor device of the first embodiment;

FIG. 4 is a schematic cross-sectional view of a semiconductor device of a first comparative example;

FIG. 5 is a schematic cross-sectional view of a semiconductor device of a second comparative example;

FIG. 6 is a schematic cross-sectional view of a semiconductor device of a second embodiment; and

FIG. 7 is a schematic cross-sectional view of a semiconductor device of a third embodiment.

### DETAILED DESCRIPTION

A semiconductor device of an embodiment includes: a device region; and a termination region surrounding the device region, wherein the device region includes: a first electrode; a second electrode; a silicon carbide layer provided between the first electrode and the second electrode and having a first face on a side of the first electrode and a second face on a side of the second electrode, the silicon carbide layer including: a first silicon carbide region of a first conductive type including a first region and a second region provided between the first region and the first face; a second silicon carbide region of a second conductive type provided between the second region and the first face and electrically connected to the first electrode; a third silicon carbide region of a first conductive type provided between the second silicon carbide region and the first face and electrically connected to the first electrode; and a fourth silicon carbide region of a second conductive type provided between the first region and the second region; a gate electrode provided in the silicon carbide layer and facing the fourth silicon carbide region, the second region, the second silicon carbide region, and the third silicon carbide region; and a gate insulating layer provided between the gate electrode and the silicon carbide layer, the termination region includes: the second electrode; and the silicon carbide layer including: the first silicon carbide region including the first region and the second region; a fifth silicon carbide region of a second conductive type provided between the second region and the first face and electrically connected to the first electrode; a plurality of sixth silicon carbide regions of a second conductive type provided between the second region and the first face, disposed in a first direction from the device region toward the termination region with respect to the fifth silicon carbide region, spaced apart from the fifth silicon carbide region, and spaced apart from each other in the first direction; a seventh silicon carbide region of a second conductive type provided between the first region and the second region and electrically connected to the first electrode; at least one eighth silicon carbide region of a second conductive type provided between the first region and the second region, disposed in the first direction with respect to the seventh silicon carbide region, and spaced apart from the seventh silicon carbide region; and at least one ninth silicon carbide region of a second conductive type provided between the second region and the first face, disposed in the first direction with respect to the sixth silicon carbide region, and spaced apart from the sixth silicon carbide region, wherein a first position of an end portion of the seventh silicon carbide region on a side opposite to the device region in the first direction is disposed closer to the device region than a second position of an end portion of the fifth silicon carbide region on a side opposite to the device region in the first direction, a third position of an end portion of one of the at least one eighth silicon carbide region on a side opposite to the device region in the first direction, the one of the at least one eighth silicon carbide region being farthest from the device region in the first direction among the at least one eighth silicon carbide region, is disposed closer to the device region than a fourth position of an end portion of one of the sixth silicon carbide region on a side opposite to the device region in the first direction, the one of the sixth silicon carbide region being farthest from the device region in the first direction among the sixth silicon carbide regions, the third position being disposed farther from the device region in the first direction than a fifth position of an end portion of another one of the sixth silicon carbide regions on the side opposite to the device region in the first direction, the another one of the sixth silicon carbide regions being second farthest from the device region in the first direction among the sixth silicon carbide regions, and a first distance between one of the at least one ninth silicon carbide region closest to the device region in the first direction among the at least one ninth silicon carbide region and the one of the sixth silicon carbide regions is less than a second distance between the one of the sixth silicon carbide region and the another one of the sixth silicon carbide regions.

Hereinafter, embodiments of the present disclosure will be described with reference to the drawings. Note that, in the following description, the same or similar members and the like are denoted by the same reference numerals, and the descriptions of the members and the like once described may be appropriately omitted.

In addition, in the following description, when there are notations of n⁺, n, n⁻, p⁺, p, and p⁻, these notations indicate relative levels of impurity concentrations in respective conductive types. That is, n⁺ indicates an n-type impurity concentration relatively higher than that of n, and n⁻ indicates an n-type impurity concentration relatively lower than that of n. In addition, p⁺ indicates a p-type impurity concentration relatively higher than that of p, and p⁻ indicates a p-type impurity concentration relatively lower than that of p. Note that an n⁺-type and an n⁻-type may be simply referred to as an n-type, and a p⁺-type and a p⁻-type may be simply referred to as a p-type.

Note that, in the present specification, unless otherwise specified, the term “impurity concentration” refers to a concentration obtained by compensating for a concentration of impurities of an opposite conductive type. That is, an n-type impurity concentration in a silicon carbide region of n-type refers to a concentration obtained by subtracting a concentration of p-type impurities from a concentration of n-type impurities. In addition, a p-type impurity concentration in a silicon carbide region of p-type refers to a concentration obtained by subtracting a concentration of n-type impurities from a concentration of p-type impurities. Note that, in the present specification, unless otherwise specified, the “impurity concentration in the silicon carbide region” is the maximum impurity concentration in the corresponding silicon carbide region.

An impurity concentration can be measured by, for example, secondary ion mass spectrometry (SIMS). In addition, a relative level of the impurity concentration can also be determined from a level of a carrier concentration determined by, for example, scanning capacitance microscopy (SCM). In addition, a distance such as a depth and a thickness of an impurity region can be determined, for example, by SIMS or a scanning electron microscope (SEM). In addition, a distance such as a depth, a thickness, a width, or a spacing of an impurity region can be determined, for example, from a composite image of an SCM image and an atomic force microscope (AFM) image.

### (First Embodiment)

A semiconductor device of a first embodiment includes a device region and a termination region surrounding the device region. The device region includes a first electrode, a second electrode, and a silicon carbide layer provided between the first electrode and the second electrode and having a first face on a side of the first electrode and a second face on a side of the second electrode, the silicon carbide layer including: a first silicon carbide region of a first conductive type including a first region and a second region provided between the first region and the first face; a second silicon carbide region of a second conductive type provided between the second region and the first face and electrically connected to the first electrode; a third silicon carbide region of a first conductive type provided between the second silicon carbide region and the first face and electrically connected to the first electrode; and a fourth silicon carbide region of a second conductive type provided between the first region and the second region, a gate electrode provided in the silicon carbide layer and facing the fourth silicon carbide region, the second region, the second silicon carbide region, and the third silicon carbide region, and a gate insulating layer provided between the gate electrode and the silicon carbide layer. The termination region includes the second electrode; and the silicon carbide layer including: the first silicon carbide region including the first region and the second region; a fifth silicon carbide region of a second conductive type provided between the second region and the first face and electrically connected to the first electrode; a plurality of sixth silicon carbide regions of a second conductive type provided between the second region and the first face, disposed in a first direction from the device region toward the termination region with respect to the fifth silicon carbide region, spaced apart from the fifth silicon carbide region, and spaced apart from each other in the first direction; a seventh silicon carbide region of a second conductive type provided between the first region and the second region and electrically connected to the first electrode; one or more eighth silicon carbide regions of a second conductive type provided between the first region and the second region, disposed in the first direction with respect to the seventh silicon carbide region, and spaced apart from the seventh silicon carbide region; and one or more ninth silicon carbide regions of a second conductive type provided between the second region and the first face, disposed in the first direction with respect to the sixth silicon carbide region, and spaced apart from the sixth silicon carbide region. A first position of an end portion of the seventh silicon carbide region on a side opposite to the device region in the first direction is disposed closer to the device region than a second position of an end portion of the fifth silicon carbide region on a side opposite to the device region in the first direction, a third position of an end portion of the eighth silicon carbide region on a side opposite to the device region in the first direction, the eighth silicon carbide region being farthest from the device region in the first direction among the one or more eighth silicon carbide regions, is disposed closer to the device region than a fourth position of an end portion of the sixth silicon carbide region on a side opposite to the device region in the first direction, the sixth silicon carbide region being farthest from the device region in the first direction among the sixth silicon carbide regions, the third position being disposed farther from the device region in the first direction than a fifth position of an end portion of the sixth silicon carbide region on the side opposite to the device region in the first direction, the sixth silicon carbide region being second farthest from the device region in the first direction among the sixth silicon carbide regions, and a first distance between the ninth silicon carbide region closest to the device region in the first direction among the one or more ninth silicon carbide regions and the sixth silicon carbide region farthest from the device region in the first direction among the sixth silicon carbide regions is less than a second distance between the sixth silicon carbide region farthest from the device region in the first direction among the sixth silicon carbide regions and the sixth silicon carbide region second farthest from the device region in the first direction among the sixth silicon carbide regions.

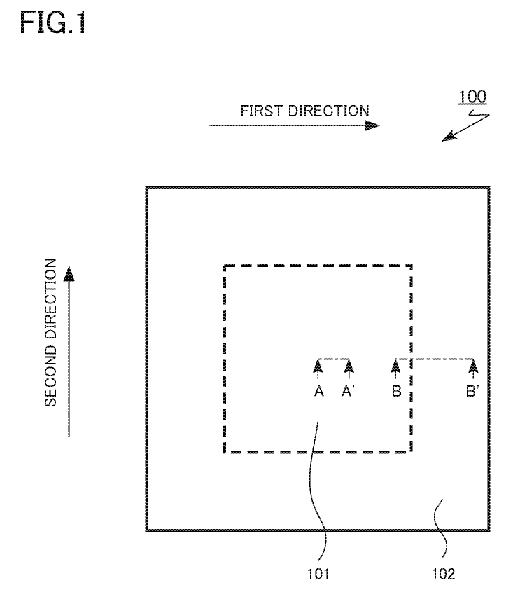

FIG. 1 is a schematic top view of the semiconductor device of the first embodiment. FIG. 1 illustrates a layout pattern of a device region and a termination region.

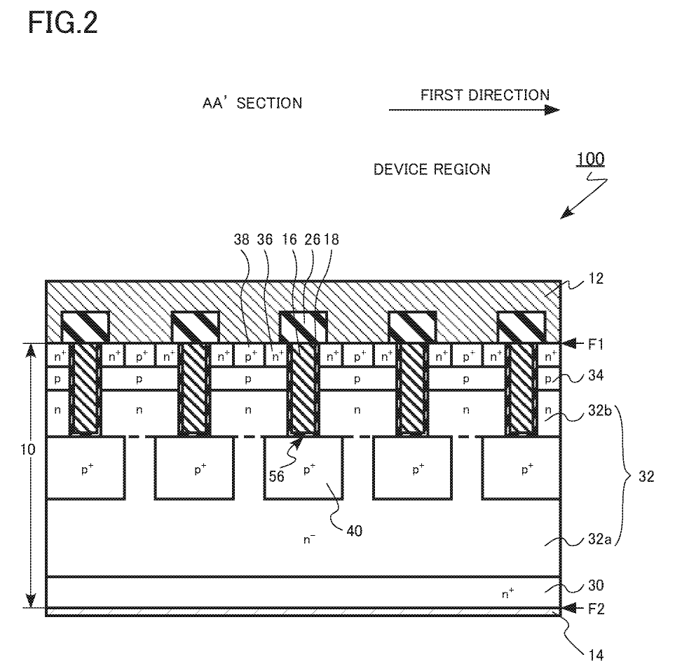

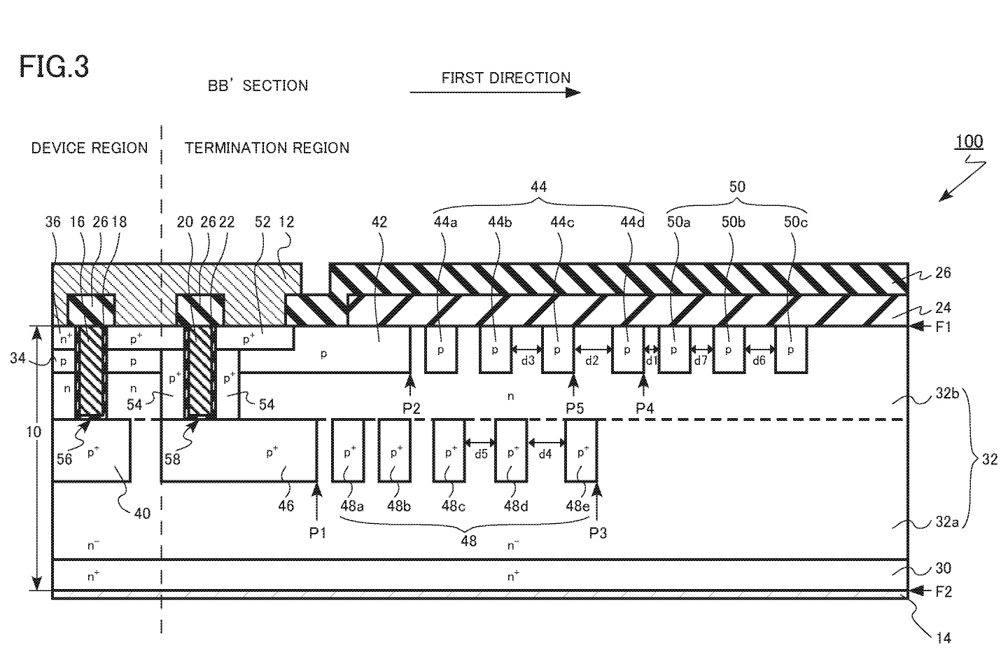

FIGS. 2 and 3 are schematic cross-sectional views of the semiconductor device of the first embodiment. FIG. 2 is a cross section taken along line AA’ illustrated in FIG. 1. FIG. 3 is a cross section taken along line BB’ illustrated in FIG. 1.

The semiconductor device of the first embodiment is a vertical MOSFET 100 using silicon carbide. The MOSFET 100 is, for example, a double implantation MOSFET (DIMOSFET) in which a base region and a source region are formed by ion implantation. The MOSFET 100 is a trench gate type MOSFET in which a gate electrode is provided in a trench.

Hereinafter, a case where a first conductive type is an n-type and a second conductive type is a p-type will be described by way of example. The MOSFET 100 is a MOSFET of a vertical n-channel type using electrons as carriers.

The MOSFET 100 includes a silicon carbide layer 10, a source electrode 12 (first electrode), a drain electrode 14 (second electrode), a gate electrode 16, a gate insulating layer 18, a conductive layer 20, a trench insulating layer 22 (insulating layer), a field insulating layer 24, and an interlayer insulating layer 26.

The silicon carbide layer 10 includes a drain region 30 of n⁺-type, a drift region 32 of n-type (first silicon carbide region), a cell base region 34 of p-type (second silicon carbide region), a source region 36 of n⁺-type (third silicon carbide region), a cell contact region 38 of p⁺-type, a cell bottom region 40 of p⁺-type (fourth silicon carbide region), a termination base region 42 of p-type (fifth silicon carbide region), an upper guard ring region 44 of p-type (sixth silicon carbide region), a termination bottom region 46 of p⁺-type (seventh silicon carbide region), a lower guard ring region 48 of p⁺-type (eighth silicon carbide region), an outer peripheral guard ring region 50 of p-type (ninth silicon carbide region), a termination contact region 52 of p⁺-type, a connection region 54 of p⁺-type (tenth silicon carbide region), a gate trench 56, and a termination trench 58.

The drift region 32 includes a lower region 32a (first region) and an upper region 32b (second region). The upper guard ring region 44 includes a first upper guard ring region 44a, a second upper guard ring region 44b, a third upper guard ring region 44c, and a fourth upper guard ring region 44d. The lower guard ring region 48 includes a first lower guard ring region 48a, a second lower guard ring region 48b, a third lower guard ring region 48c, a fourth lower guard ring region 48d, and a fifth lower guard ring region 48e. The outer peripheral guard ring region 50 includes a first outer peripheral guard ring region 50a, a second outer peripheral guard ring region 50b, and a third outer peripheral guard ring region 50c.

The MOSFET 100 includes a device region 101 and a termination region 102. The termination region 102 surrounds the device region 101. The termination region 102 is provided outside the device region 101. The device region 101 is provided inside the termination region 102.

The device region 101 includes a plurality of transistors. The termination region 102 relaxes the intensity of an electric field applied to a termination portion of a pn junction of the device region 101 when the transistor is in an off state. The termination region 102 has a function of improving a breakdown voltage of the MOSFET 100.

The device region 101 includes a silicon carbide layer 10, a source electrode 12, a drain electrode 14, a gate electrode 16, a gate insulating layer 18, and an interlayer insulating layer 26.

The silicon carbide layer 10 of the device region 101 includes a drain region 30 of n⁺-type, a drift region 32 of n-type (first silicon carbide region), a cell base region 34 of p-type (second silicon carbide region), a source region 36 of n⁺-type (third silicon carbide region), a cell contact region 38 of p⁺-type, a cell bottom region 40 of p⁺-type (fourth silicon carbide region), and a gate trench 56.

The termination region 102 includes a silicon carbide layer 10, a source electrode 12, a drain electrode 14, a conductive layer 20, a trench insulating layer 22, a field insulating layer 24, and an interlayer insulating layer 26.

The silicon carbide layer 10 in the termination region 102 includes a drain region 30 of n⁺-type, a drift region 32 of n-type (first silicon carbide region), a termination base region 42 of p-type (fifth silicon carbide region), an upper guard ring region 44 of p-type (sixth silicon carbide region), a termination bottom region 46 of p⁺-type (seventh silicon carbide region), a lower guard ring region 48 of p⁺-type (eighth silicon carbide region), an outer peripheral guard ring region 50 of p-type (ninth silicon carbide region), a termination contact region 52 of p⁺-type, a connection region 54 of p⁺-type (tenth silicon carbide region), and a termination trench 58.

The silicon carbide layer 10 is provided between the source electrode 12 and the drain electrode 14. The silicon carbide layer 10 is single crystal SiC. The silicon carbide layer 10 is, for example, 4H-SiC.

The silicon carbide layer 10 has a first face (“F1” in FIGS. 2 and 3) and a second face (“F2” in FIGS. 2 and 3). The first face F1 is a surface of the silicon carbide layer. The second face F2 is a back surface of the silicon carbide layer. Hereinafter, the first face F1 may be referred to as a surface, and the second face F2 may be referred to as a back surface. The first face F1 is disposed on a side of the silicon carbide layer 10 close to the source electrode 12. In addition, the second face F2 is disposed on a side of the silicon carbide layer 10 close to the drain electrode 14. The first face F1 and the second face F2 face each other. Note that, hereinafter, the term “depth” refers to a depth in a direction toward the second face based on the first face. The “face” of each of the first face F1 and the second face F2 indicates, for example, an interface between the silicon carbide layer and the insulating layer or between the silicon carbide layer and the metal.

One direction parallel to the first face is defined as a first direction. The first direction is a direction from the device region 101 toward the termination region 102. In addition, a direction parallel to the first face and perpendicular to the first direction is defined as a second direction.

The first face F1 is, for example, a face inclined at equal to or more than 0° and equal to or less than 8° with respect to a (0001) face. In addition, the second face F2 is, for example, a face inclined at equal to or more than 0° and equal to or less than 8° with respect to a (000-1) face. The (0001) face is referred to as a silicon face. The (000-1) face is referred to as a carbon face.

A thickness of the silicon carbide layer 10 is, for example, equal to or more than 5 μm and equal to or less than 350 μm.

The drain region 30 of n⁺-type is provided on a back surface of the silicon carbide layer 10. The drain region 30 contains, for example, nitrogen (N) as n-type impurities. An n-type impurity concentration in the drain region 30 is, for example, equal to or more than 1 × 10¹⁸ cm⁻³ and equal to or less than 1 × 10²¹ cm⁻³.

The drift region 32 of n-type is provided between the drain region 30 and the first face F1. The drift region 32 of n-type is provided between the source electrode 12 and the drain electrode 14. The drift region 32 of n-type is provided between the gate electrode 16 and the drain electrode 14. The drift region 32 of n-type is provided on the drain region 30.

The drift region 32 functions as, for example, a current path when the MOSFET 100 is in an on state. In addition, the drift region 32 has a function of forming a depletion layer and maintaining a breakdown voltage, for example, when the MOSFET 100 is in an off state.

The drift region 32 contains, for example, nitrogen (N) as n-type impurities. An n-type impurity concentration in the drift region 32 is lower than the n-type impurity concentration in the drain region 30. The n-type impurity concentration in the drift region 32 is, for example, equal to or more than 4 × 10¹⁴ cm⁻³ and equal to or less than 5 × 10¹⁷ cm⁻³. A thickness of the drift region 32 is, for example, equal to or more than 3 μm and equal to or less than 100 μm.

The drift region 32 includes a lower region 32a and an upper region 32b. The upper region 32b is provided between the lower region 32a and the first face F1. An n-type impurity concentration in the upper region 32b is, for example, higher than an n-type impurity concentration in the lower region 32a. The n-type impurity concentration in the upper region 32b may be, for example, substantially equal to the n-type impurity concentration in the lower region 32a.

A depth of the upper region 32b is, for example, equal to or more than 0.5 μm and equal to or less than 2 μm.

The cell base region 34 of p-type is provided between the drift region 32 and the first face F1. The cell base region 34 is provided between the upper region 32b and the first face F1.

The cell base region 34 functions as, for example, a channel region of the MOSFET 100.

A part of the cell base region 34 faces the gate electrode 16. The gate insulating layer 18 is sandwiched between a part of the cell base region 34 and the gate electrode 16.

The cell base region 34 contains, for example, aluminum (Al) as p-type impurities. A p-type impurity concentration in the cell base region 34 is, for example, equal to or more than 5 × 10¹⁶ cm⁻³ and equal to or less than 1 × 10¹⁹ cm⁻³.

The cell base region 34 is electrically connected to the source electrode 12. The cell base region 34 is fixed to an electric potential of the source electrode 12.

The source region 36 of n⁺-type is provided between the cell base region 34 and the first face F1. The source region 36 extends, for example, in the second direction.

The source region 36 contains, for example, phosphorus (P) or nitrogen (N) as n-type impurities. An n-type impurity concentration in the source region 36 is higher than the n-type impurity concentration in the drift region 32. The n-type impurity concentration in the source region 36 is, for example, equal to or more than 1 × 10¹⁸ cm⁻³ and equal to or less than 1 × 10²¹ cm⁻³.

The source region 36 is physically and electrically connected to the source electrode 12. The contact between the source region 36 and the source electrode 12 is, for example, an ohmic contact. The source region 36 is fixed to the electric potential of the source electrode 12.

The cell contact region 38 of p⁺-type is provided between the cell base region 34 and the first face F1. The cell contact region 38 is in contact with the cell base region 34. The cell contact region 38 extends, for example, in the second direction.

The cell contact region 38 contains, for example, aluminum (Al) as p-type impurities. A p-type impurity concentration in the cell contact region 38 is higher than the p-type impurity concentration in the cell base region 34. The p-type impurity concentration in the cell contact region 38 is, for example, equal to or more than 1 × 10¹⁹ cm⁻³ and equal to or less than 1 × 10²¹ cm⁻³.

The cell contact region 38 is physically and electrically connected to the source electrode 12. The contact between the cell contact region 38 and the source electrode 12 is, for example, an ohmic contact. The cell contact region 38 is fixed to the electric potential of the source electrode 12.

The cell bottom region 40 of p⁺-type is provided between the lower region 32a and the upper region 32b. The cell bottom region 40 is provided between the gate trench 56 and the lower region 32a. The cell bottom region 40 is in contact with the gate trench 56. The cell bottom region 40 extends, for example, in the second direction.

The cell bottom region 40 has a function of relaxing the intensity of an electric field applied to the gate insulating layer 18 at the bottom of the gate trench 56 when the MOSFET 100 is in an off state.

The cell bottom region 40 contains, for example, aluminum (Al) as p-type impurities. A p-type impurity concentration in the cell bottom region 40 is higher than the p-type impurity concentration in the cell base region 34. The p-type impurity concentration in the cell bottom region 40 is, for example, equal to or more than 1 × 10¹⁸ cm⁻³ and equal to or less than 1 × 10²¹ cm⁻³.

The gate trench 56 is provided on a side of the first face F1 of the silicon carbide layer 10. The gate trench 56 is a groove provided in the silicon carbide layer 10. The gate trench 56 is a part of the silicon carbide layer 10.

The gate trench 56 extends, for example, in the second direction on the first face F1. The gate trench 56 is repeatedly provided in the first direction on the first face, for example.

The gate trench 56 is in contact with, for example, the cell bottom region 40, the upper region 32b, the cell base region 34, and the source region 36.

A depth of the gate trench 56 is, for example, equal to or more than 0.5 μm and equal to or less than 2 μm.

The gate electrode 16 is provided in the gate trench 56. The gate electrode 16 faces the cell bottom region 40, the upper region 32b, the cell base region 34, and the source region 36. The gate electrode 16 is provided, for example, between a part of the cell base region 34 and another part of the cell base region 34 in the first direction.

The gate electrode 16 extends, for example, in the second direction. A plurality of gate electrodes 16 are disposed, for example, in parallel with each other in the first direction. The gate electrode 16 has, for example, a stripe shape.

The gate electrode 16 is a conductor. The gate electrode 16 is, for example, polycrystalline silicon containing p-type impurities or n-type impurities.

The gate insulating layer 18 is provided between the gate electrode 16 and the silicon carbide layer 10. The gate insulating layer 18 is provided between the gate electrode 16 and the cell bottom region 40. The gate insulating layer 18 is provided between the gate electrode 16 and the upper region 32b. The gate insulating layer 18 is provided between the gate electrode 16 and the cell base region 34. The gate insulating layer 18 is provided between the gate electrode 16 and the source region 36.

The gate insulating layer 18 is an insulator. The gate insulating layer 18 is, for example, silicon oxide. For example, a high-k insulating material (high dielectric constant insulating material) can be applied to the gate insulating layer 18.

The interlayer insulating layer 26 is provided on the gate electrode 16 and the silicon carbide layer 10. The interlayer insulating layer 26 is, for example, silicon oxide.

The interlayer insulating layer 26 has, for example, a function of electrically separating the gate electrode 16 and the source electrode 12.

The termination base region 42 of p-type is provided between the upper region 32b and the first face F1. A part of the termination base region 42 is in contact with the first face F1. A part of the termination base region 42 is in contact with, for example, the interlayer insulating layer 26 or the field insulating layer 24. The termination base region 42 is in contact with, for example, the upper region 32b.

The termination base region 42 surrounds, for example, the device region 101 on the first face F1. The termination base region 42 has, for example, an annular shape on the first face F1. The termination base region 42 surrounds, for example, the cell base region 34 and the source region 36 on the first face F1.

The termination base region 42 has a function of relaxing the intensity of an electric field applied to the termination portion of the pn junction of the device region 101 when the MOSFET 100 is in an off state.

The termination base region 42 contains, for example, aluminum (Al) as p-type impurities. A p-type impurity concentration in the termination base region 42 is, for example, substantially equal to the p-type impurity concentration in the cell base region 34. The p-type impurity concentration in the termination base region 42 is, for example, equal to or more than 5 × 10¹⁶ cm⁻³ and equal to or less than 1 × 10¹⁹ cm⁻³.

The termination base region 42 is electrically connected to the source electrode 12. The termination base region 42 is fixed to the electric potential of the source electrode 12.

The termination base region 42 is formed, for example, by the same manufacturing process using the same mask pattern as the cell base region 34.

The termination contact region 52 of p⁺-type is provided between the termination base region 42 and the first face F1. The termination contact region 52 is in contact with the termination base region 42.

The termination contact region 52 contains, for example, aluminum (Al) as p-type impurities. A p-type impurity concentration in the termination contact region 52 is higher than the p-type impurity concentration in the termination base region 42. The p-type impurity concentration in the termination contact region 52 is, for example, equal to or more than 1 × 10¹⁹ cm⁻³ and equal to or less than 1 × 10²¹ cm⁻³.

The termination contact region 52 is physically and electrically connected to the source electrode 12. The contact between the termination contact region 52 and the source electrode 12 is, for example, an ohmic contact. The termination contact region 52 is fixed to the electric potential of the source electrode 12.

A plurality of upper guard ring regions 44 of p-type are provided between the upper region 32b and the first face F1. The upper guard ring region 44 is in contact with, for example, the first face F1. The upper guard ring region 44 is in contact with, for example, the field insulating layer 24. The upper guard ring region 44 is in contact with, for example, the upper region 32b.

The upper guard ring region 44 is disposed in the first direction with respect to the termination base region 42. The upper guard ring region 44 is spaced apart from the termination base region 42. The upper guard ring regions 44 are provided spaced apart from each other in the first direction. Although FIG. 3 illustrates the case where the number of upper guard ring regions 44 is four, the number of upper guard ring regions 44 may be two, three, or equal to or greater than five.

The upper guard ring region 44 surrounds, for example, the device region 101 on the first face F1. The upper guard ring region 44 has, for example, an annular shape on the first face F1. The upper guard ring region 44 surrounds, for example, the termination base region 42 on the first face F1.

The upper guard ring region 44 has a function of relaxing the intensity of the electric field applied to the end portion of the termination base region 42 when the MOSFET 100 is in an off state.

When three or more upper guard ring regions 44 are provided, for example, a distance between two upper guard ring regions 44 adjacent in the first direction increases in the first direction. For example, a second distance (d2 in FIG. 3) between the fourth upper guard ring region 44d and the third upper guard ring region 44c is greater than a third distance (d3 in FIG. 3) between the third upper guard ring region 44c and the second upper guard ring region 44b. Similarly, the third distance (d3 in FIG. 3) between the third upper guard ring region 44c and the second upper guard ring region 44b is, for example, greater than a distance between the second upper guard ring region 44b and the first upper guard ring region 44a.

Note that the distances between the two upper guard ring regions 44 adjacent in the first direction can be made substantially equal.

A width of the upper guard ring region 44 in the first direction is, for example, equal to or more than 0.5 μm and equal to or less than 4 μm. A distance between two upper guard ring regions 44 adjacent in the first direction is, for example, equal to or more than 0.5 μm and equal to or less than 4 μm.

The upper guard ring region 44 contains, for example, aluminum (Al) as p-type impurities. A p-type impurity concentration in the upper guard ring region 44 is, for example, substantially equal to the p-type impurity concentration in the termination base region 42. The p-type impurity concentration in the termination base region 42 is, for example, equal to or more than 5 × 10¹⁶ cm⁻³ and equal to or less than 1 × 10¹⁹ cm⁻³.

The upper guard ring region 44 is electrically separated from the source electrode 12. The upper guard ring region 44 is, for example, in an electrically floating state.

The upper guard ring region 44 is formed, for example, by the same manufacturing process using the same mask pattern as the termination base region 42.

The termination bottom region 46 of p⁺-type is provided between the lower region 32a and the upper region 32b. The termination bottom region 46 is provided between the termination trench 58 and the lower region 32a. The termination bottom region 46 is in contact with, for example, the lower region 32a and the upper region 32b. The termination bottom region 46 is in contact with the termination trench 58.

The termination bottom region 46 surrounds, for example, the device region 101 in a cross section parallel to the first face F1. The termination bottom region 46 has, for example, an annular shape in a cross section parallel to the first face F1. The termination bottom region 46 surrounds, for example, the cell bottom region 40 in a cross section parallel to the first face F1.

The termination bottom region 46 has a function of relaxing the intensity of an electric field applied to the gate insulating layer 18 at the bottom of the termination trench 58. In addition, the termination bottom region 46 has a function of relaxing the intensity of the electric field applied to the termination portion of the pn junction of the device region 101 when the MOSFET 100 is in an off state.

A first position (P1 in FIG. 3) of an end portion of the termination bottom region 46 on a side opposite to the device region 101 in the first direction is disposed closer to the device region 101 than a second position (P2 in FIG. 3) of an end portion of the termination base region 42 on a side opposite to the device region 101 in the first direction.

The termination bottom region 46 contains, for example, aluminum (Al) as p-type impurities. A p-type impurity concentration in the termination bottom region 46 is, for example, higher than the p-type impurity concentration in the termination base region 42. The p-type impurity concentration in the termination bottom region 46 is, for example, equal to or more than 1 × 10¹⁸ cm⁻³ and equal to or less than 1 × 10²¹ cm⁻³.

The termination bottom region 46 is electrically connected to the source electrode 12. The termination bottom region 46 is fixed to the electric potential of the source electrode 12.

The termination bottom region 46 is formed, for example, by the same manufacturing process using the same mask pattern as the cell bottom region 40.

The connection region 54 of p⁺-type is in contact with the termination base region 42 and the termination bottom region 46. The connection region 54 is provided, for example, between the termination contact region 52 and the termination bottom region 46. The connection region 54 is in contact with, for example, the termination contact region 52. The connection region 54 is in contact with, for example, the termination trench 58.

The connection region 54 has a function of electrically connecting the source electrode 12 and the termination bottom region 46.

The connection region 54 contains, for example, aluminum (Al) as p-type impurities. A p-type impurity concentration in the connection region 54 is, for example, higher than the p-type impurity concentration in the termination base region 42. The p-type impurity concentration in the connection region 54 is, for example, equal to or more than 1 × 10¹⁸ cm⁻³ and equal to or less than 1 × 10²¹ cm⁻³.

The lower guard ring region 48 of p⁺-type is provided between the lower region 32a and the upper region 32b. The lower guard ring region 48 is in contact with, for example, the lower region 32a and the upper region 32b.

The lower guard ring region 48 is disposed in the first direction with respect to the termination bottom region 46. The lower guard ring region 48 is spaced apart from the termination bottom region 46.

For example, a plurality of lower guard ring regions 48 are provided. For example, two or more lower guard ring regions 48 are provided. When a plurality of lower guard ring regions 48 are provided, the lower guard ring regions 48 are provided spaced apart from each other in the first direction. Although FIG. 3 illustrates the case where the number of lower guard ring regions 48 is five, the number of lower guard ring regions 48 may be one to four or equal to or greater than six.

The lower guard ring region 48 surrounds, for example, the device region 101 in a cross section parallel to first face F1. The lower guard ring region 48 has, for example, an annular shape in a cross section parallel to first face F1. The lower guard ring region 48 surrounds, for example, the termination bottom region 46 in a cross section parallel to first face F1.

The lower guard ring region 48 has a function of relaxing the intensity of the electric field applied to the end portion of the termination bottom region 46 when the MOSFET 100 is in an off state.

When three or more lower guard ring regions 48 are provided, for example, a distance between two lower guard ring regions 48 adjacent in the first direction increases in the first direction. For example, a fourth distance (d4 in FIG. 3) between the fifth lower guard ring region 48e and the fourth lower guard ring region 48d is greater than a fifth distance (d5 in FIG. 3) between the fourth lower guard ring region 48d and the third lower guard ring region 48c. Similarly, the fifth distance (d5 in FIG. 3) between the fourth lower guard ring region 48d and the third lower guard ring region 48c is, for example, greater than the distance between the third lower guard ring region 48c and the second lower guard ring region 48b. Similarly, the distance between the third lower guard ring region 48c and the second lower guard ring region 48b is, for example, greater than the distance between the second lower guard ring region 48b and the first lower guard ring region 48a.

Note that the distances between the two lower guard ring regions 48 adjacent in the first direction can be made substantially equal.

A third position (P3 in FIG. 3) of an end portion of the fifth lower guard ring region 48e on a side opposite to the device region 101 in the first direction, the fifth lower guard ring region 48e being farthest from the device region 101 in the first direction among the lower guard ring regions 48, is disposed closer to the device region 101 than a fourth position (P4 in FIG. 3) of an end portion of the fourth upper guard ring region 44d on a side opposite to the device region 101 in the first direction, the fourth upper guard ring region 44d being farthest from the device region 101 in the first direction among the upper guard ring regions 44. In addition, the third position P3 is disposed farther from the device region 101 in the first direction than the fifth position (P5 in FIG. 3) of the end portion of the third upper guard ring region 44c on a side opposite to the device region 101 in the first direction, the third upper guard ring region 44c being second farthest from the device region 101 in the first direction among the upper guard ring regions 44.

A width of the lower guard ring region 48 in the first direction is, for example, equal to or more than 0.5 μm and equal to or less than 4 μm. A distance between two lower guard ring regions 48 adjacent in the first direction is, for example, equal to or more than 0.5 μm and equal to or less than 4 μm.

The lower guard ring region 48 contains, for example, aluminum (Al) as p-type impurities. A p-type impurity concentration in the lower guard ring region 48 is, for example, substantially equal to the p-type impurity concentration in the termination bottom region 46. The p-type impurity concentration in the lower guard ring region 48 is, for example, higher than the p-type impurity concentration in the termination base region 42. The p-type impurity concentration in the lower guard ring region 48 is, for example, higher than the p-type impurity concentration in the upper guard ring region 44. The p-type impurity concentration in the lower guard ring region 48 is, for example, higher than the p-type impurity concentration in the outer peripheral guard ring region 50. The p-type impurity concentration in the lower guard ring region 48 is, for example, equal to or more than 1 × 10¹⁸ cm⁻³ and equal to or less than 1 × 10²¹ cm⁻³.

The lower guard ring region 48 is electrically separated from the source electrode 12. The lower guard ring region 48 is, for example, in an electrically floating state.

The lower guard ring region 48 is formed, for example, by the same manufacturing process using the same mask pattern as the termination bottom region 46.

The outer peripheral guard ring region 50 of p-type is provided between the upper region 32b and the first face F1. The outer peripheral guard ring region 50 is in contact with, for example, the first face F1. The outer peripheral guard ring region 50 is in contact with, for example, the field insulating layer 24. The outer peripheral guard ring region 50 is in contact with, for example, the upper region 32b.

The outer peripheral guard ring region 50 is disposed in the first direction with respect to the upper guard ring region 44. The outer peripheral guard ring region 50 is provided outside the upper guard ring region 44. The outer peripheral guard ring region 50 is spaced apart from the upper guard ring region 44.

For example, a plurality of outer peripheral guard ring regions 50 are provided. For example, two or more outer peripheral guard ring regions 50 are provided. When a plurality of outer peripheral guard ring regions 50 are provided, the outer peripheral guard ring regions 50 are provided spaced apart from each other in the first direction. Although FIG. 3 illustrates the case where the number of outer peripheral guard ring regions 50 is three, the number of outer peripheral guard ring regions 50 may be one, two, or equal to or greater than four.

The outer peripheral guard ring region 50 surrounds, for example, the device region 101 on the first face F1. The outer peripheral guard ring region 50 has, for example, an annular shape on the first face F1. The outer peripheral guard ring region 50 surrounds, for example, the upper guard ring region 44 on the first face F1.

The outer peripheral guard ring region 50 has a function of relaxing the intensity of the electric field applied to the end portion of the upper guard ring region 44 when the MOSFET 100 is in an off state.

When three or more outer peripheral guard ring regions 50 are provided, for example, a distance between two outer peripheral guard ring regions 50 adjacent in the first direction increases in the first direction. For example, a sixth distance (d6 in FIG. 3) between the third outer peripheral guard ring region 50c and the second outer peripheral guard ring region 50b is greater than a seventh distance (d7 in FIG. 3) between the second outer peripheral guard ring region 50b and the first outer peripheral guard ring region 50a.

Note that the distances between the two outer peripheral guard ring regions 50 adjacent in the first direction can be made substantially equal.

A first distance (d1 in FIG. 3) between the first outer peripheral guard ring region 50a closest to the device region in the first direction among the outer peripheral guard ring regions 50 and the fourth upper guard ring region 44d farthest from the device region 101 in the first direction among the upper guard ring regions 44 is less than a second distance (d2 in FIG. 3) between the fourth upper guard ring region 44d farthest from the device region 101 in the first direction among the upper guard ring regions 44 and the third upper guard ring region 44c second farthest from the device region 101 in the first direction among the upper guard ring regions 44.

The first distance d1 is, for example, equal to or more than one tenth and equal to or less than one fourth of the second distance d2.

A width of the outer peripheral guard ring region 50 in the first direction is, for example, equal to or more than 0.5 μm and equal to or less than 4 μm. A distance between two outer peripheral guard ring regions 50 adjacent in the first direction is, for example, equal to or more than 0.5 μm and equal to or less than 4 μm.

The outer peripheral guard ring region 50 contains, for example, aluminum (Al) as p-type impurities. A p-type impurity concentration in the outer peripheral guard ring region 50 is, for example, substantially equal to the p-type impurity concentration in the upper guard ring region 44. The p-type impurity concentration in the outer peripheral guard ring region 50 is, for example, equal to or more than 5 × 10¹⁶ cm⁻³ and equal to or less than 1 × 10¹⁹ cm⁻³.

The outer peripheral guard ring region 50 is electrically separated from the source electrode 12. The outer peripheral guard ring region 50 is, for example, in an electrically floating state.

The outer peripheral guard ring region 50 is formed, for example, by the same manufacturing process using the same mask pattern as the termination base region 42 or the upper guard ring region 44.

The termination trench 58 is provided on a side of the first face F1 of the silicon carbide layer 10. The termination trench 58 is a groove provided in the silicon carbide layer 10. The termination trench 58 is a part of the silicon carbide layer 10.

The termination trench 58 is in contact with, for example, the termination bottom region 46, the connection region 54, and the termination contact region 52.

A depth of the termination trench 58 is, for example, equal to or more than 0.5 μm and equal to or less than 2 μm.

The conductive layer 20 is provided in the termination trench 58. The conductive layer 20 faces the termination bottom region 46, the connection region 54, and the termination contact region 52.

The conductive layer 20 is a conductor. The conductive layer 20 is, for example, polycrystalline silicon containing p-type impurities or n-type impurities.

The conductive layer 20 is, for example, electrically connected to the source electrode 12. The conductive layer 20 may be, for example, in an electrically floating state.

The trench insulating layer 22 is provided between the conductive layer 20 and the silicon carbide layer 10. The trench insulating layer 22 is provided between the conductive layer 20 and the termination bottom region 46. The trench insulating layer 22 is provided between the conductive layer 20 and the connection region 54. The trench insulating layer 22 is provided between the conductive layer 20 and the termination contact region 52.

The trench insulating layer 22 is an insulator. The trench insulating layer 22 is, for example, silicon oxide. For example, a high-k insulating material (high dielectric constant insulating material) can be applied to the trench insulating layer 22.

The interlayer insulating layer 26 is provided on the conductive layer 20 and the silicon carbide layer 10. The interlayer insulating layer 26 is, for example, silicon oxide.

The field insulating layer 24 is provided between the silicon carbide layer 10 and the interlayer insulating layer 26. The field insulating layer 24 is in contact with, for example, the first face F1. The field insulating layer 24 is, for example, silicon oxide.

Next, a function and effect of the semiconductor device of the first embodiment will be described.

In a vertical MOSFET using silicon carbide, for example, a termination region is provided around a device region including a transistor. The termination region relaxes the intensity of an electric field applied to a termination portion of a pn junction of the device region when the MOSFET is in an off state. The termination region has a function of improving a breakdown voltage of the MOSFET.

During operation of the MOSFET, for example, charge may be trapped in an insulating layer on the termination region. The charge is, for example, electrons or holes injected from the silicon carbide layer, or mobile ions that enter from outside the MOSFET.

When charge is trapped in the insulating layer, the electric field distribution in the termination region may change, and the breakdown voltage of the MOSFET may decrease. A decrease in the breakdown voltage of the MOSFET may reduce the reliability of the MOSFET.

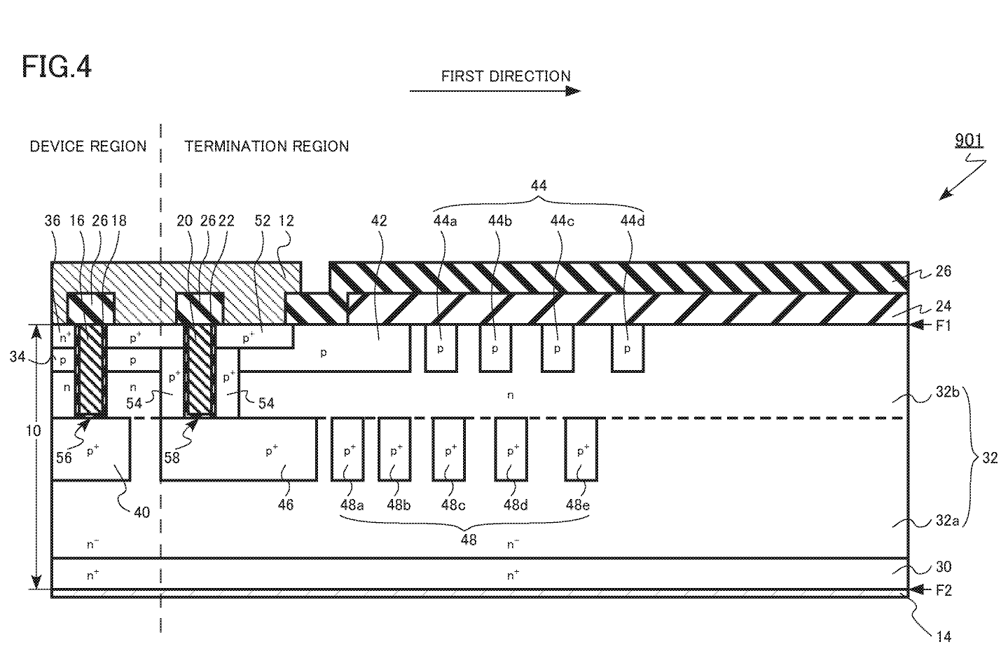

FIG. 4 is a schematic cross-sectional view of a semiconductor device of a first comparative example. FIG. 4 is a view corresponding to FIG. 3 of the first embodiment.

The semiconductor device of the first comparative example is a MOSFET 901. The MOSFET 901 differs from the MOSFET 100 of the first embodiment in that the outer peripheral guard ring region 50 of p-type is not provided outside the upper guard ring region 44 of p-type.

For example, a case is considered in which a negative charge is trapped in the field insulating layer 24 on the upper guard ring region 44 or in the interlayer insulating layer 26 on the upper guard ring region 44 during operation of the MOSFET 901. When a negative charge is trapped in the field insulating layer 24 or the interlayer insulating layer 26, a depletion layer easily extends in the drift region 32 due to the influence of the negative charge.

As the depletion layer easily extends in the drift region 32, for example, the intensity of an electric field applied to an outer end portion of the fourth upper guard ring region 44d, which is disposed outermost in the upper guard ring regions 44, increases. Therefore, the breakdown voltage of the MOSFET 901 decreases.

In the MOSFET 100 of the first embodiment, the outer peripheral guard ring region 50 is provided outside the upper guard ring region 44. A first distance d1 between the first outer peripheral guard ring region 50a closest to the device region in the first direction among the outer peripheral guard ring regions 50 and the fourth upper guard ring region 44d farthest from the device region 101 in the first direction among the upper guard ring regions 44 is less than a second distance d2 between the fourth upper guard ring region 44d farthest from the device region 101 in the first direction among the upper guard ring regions 44 and the third upper guard ring region 44c second farthest from the device region 101 in the first direction among the upper guard ring regions 44.

With the above structure, even when the depletion layer is likely to extend in the drift region due to the influence of the negative charge, the intensity of the electric field applied to the outer end portion of the fourth upper guard ring region 44d can be reduced. Therefore, it is possible to suppress a decrease in breakdown voltage when a negative charge is trapped in the insulating layer on the termination region.

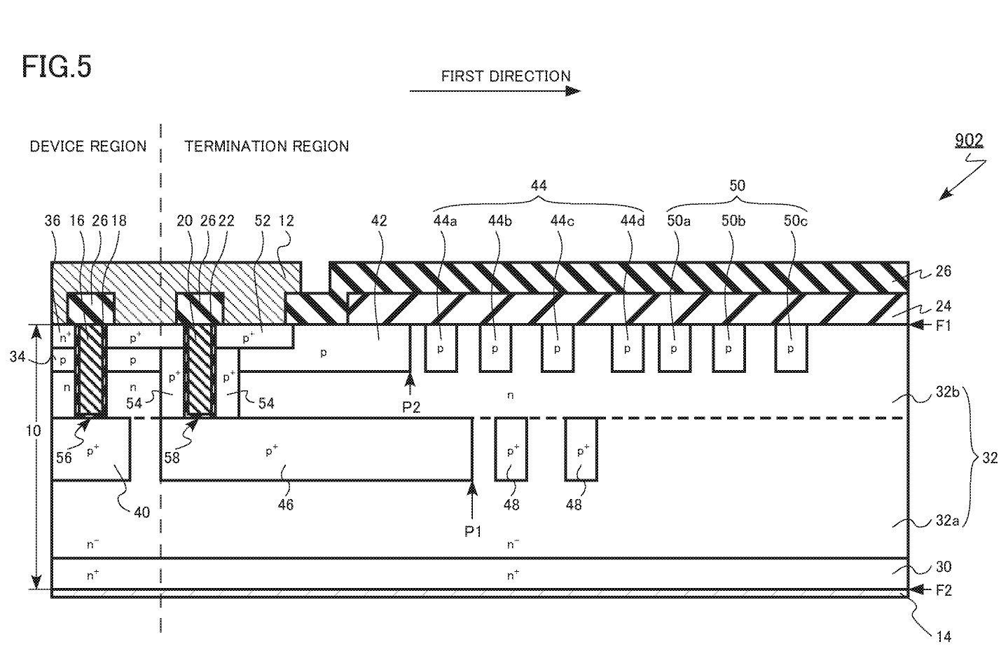

FIG. 5 is a schematic cross-sectional view of a semiconductor device of a second comparative example. FIG. 5 is a view corresponding to FIG. 3 of the first embodiment.

The semiconductor device of the second comparative example is a MOSFET 902. The MOSFET 902 differs from the MOSFET 100 of the first embodiment in that a first position P1 of an end portion of the termination bottom region 46 on a side opposite to the device region 101 in the first direction is disposed farther from the device region 101 than a second position P2 of an end portion of the termination base region 42 on a side opposite to the device region 101 in the first direction.

For example, a case is considered in which a positive charge is trapped in the field insulating layer 24 above the termination bottom region 46 or in the interlayer insulating layer 26 above the termination bottom region 46 during operation of the MOSFET 902. When a positive charge is trapped in the field insulating layer 24 or the interlayer insulating layer 26, a depletion layer tends to be less likely to extend in the drift region 32 due to the influence of the positive charge.

As the depletion layer is less likely to extend in the drift region 32, for example, the intensity of the electric field applied to the outer end portion of the termination bottom region 46 increases. Therefore, the breakdown voltage of the MOSFET 902 decreases.

In the MOSFET 100 of the first embodiment, a first position (P1 in FIG. 3) of an end portion of the termination bottom region 46 on a side opposite to the device region 101 in the first direction is disposed closer to the device region 101 than a second position (P2 in FIG. 3) of an end portion of the termination base region 42 on a side opposite to the device region 101 in the first direction.

With the above structure, even when the depletion layer is less likely to extend in the drift region due to the influence of the positive charge, the intensity of the electric field applied to the outer end portion of the termination bottom region 46 can be reduced. Therefore, it is possible to suppress a decrease in breakdown voltage when a positive charge is trapped in the insulating layer on the termination region.

As described above, according to the first embodiment, even when either a negative charge or a positive charge is trapped in the field insulating layer 24 on the termination region 102 or the interlayer insulating layer 26 on the termination region 102 during the operation of the MOSFET 100, it is possible to suppress a decrease in the breakdown voltage of the MOSFET 100. Therefore, the MOSFET 100 with high reliability can be realized.

As described above, according to the first embodiment, it is possible to realize a MOSFET capable of suppressing a decrease in breakdown voltage.

### (Second Embodiment)

A semiconductor device of a second embodiment differs from the semiconductor device according to the first embodiment in that a second conductive type impurity concentration in a sixth silicon carbide region is higher than a second conductive type impurity concentration in a fifth silicon carbide region. Hereinafter, some descriptions of contents overlapping with the first embodiment may be omitted.

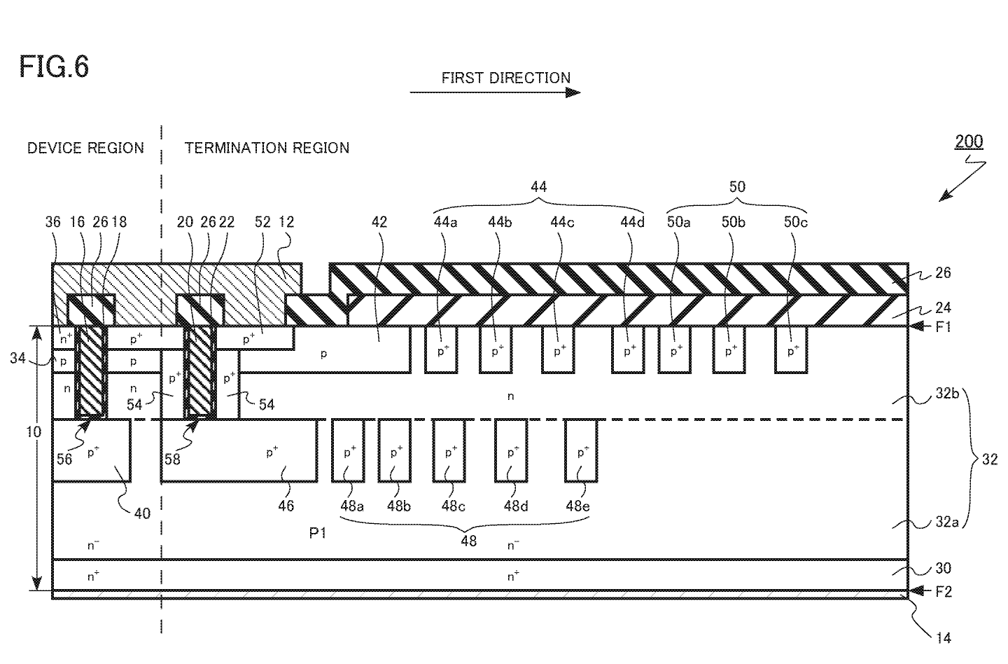

FIG. 6 is a schematic cross-sectional view of the semiconductor device of the second embodiment. FIG. 6 is a view corresponding to FIG. 3 of the first embodiment.

The semiconductor device of the second embodiment is a MOSFET 200.

A p-type impurity concentration in an upper guard ring region 44 (sixth silicon carbide region) is higher than a p-type impurity concentration in a termination base region 42 (fifth silicon carbide region). The p-type impurity concentration in the upper guard ring region 44 is lower than a p-type impurity concentration of a lower guard ring region 48 (eighth silicon carbide region).

The p-type impurity concentration in the upper guard ring region 44 is, for example, equal to or more than 1 × 10¹⁸ cm⁻³ and equal to or less than 5 × 10²⁰ cm⁻³.

In addition, for example, a p-type impurity concentration in the outer peripheral guard ring region 50 is substantially equal to the p-type impurity concentration in the upper guard ring region 44.

As described above, according to the second embodiment, similarly to the first embodiment, it is possible to realize a MOSFET capable of suppressing a decrease in breakdown voltage.

### (Third Embodiment)

A semiconductor device of a third embodiment differs from the semiconductor device according to the first embodiment in that a second conductive type impurity concentration in an eighth silicon carbide region is lower than a second conductive type impurity concentration in a seventh silicon carbide region. Hereinafter, some descriptions of contents overlapping with the first embodiment may be omitted.

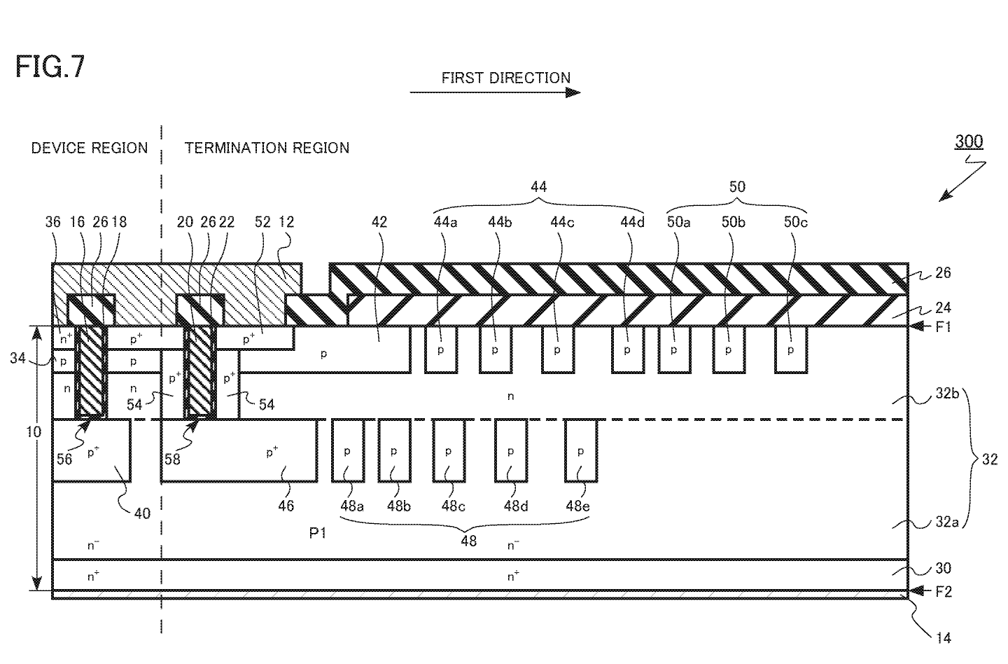

FIG. 7 is a schematic cross-sectional view of the semiconductor device of the third embodiment. FIG. 7 is a view corresponding to FIG. 3 of the first embodiment.

The semiconductor device of the third embodiment is a MOSFET 300.

A p-type impurity concentration in a lower guard ring region 48 (eighth silicon carbide region) is lower than a p-type impurity concentration in a termination bottom region 46 (seventh silicon carbide region). In addition, the p-type impurity concentration in the lower guard ring region 48 is higher than a p-type impurity concentration of an upper guard ring region 44 (sixth silicon carbide region).

The p-type impurity concentration in the lower guard ring region 48 is, for example, equal to or more than 1 × 10¹⁷ cm⁻³ and equal to or less than 5 × 10²⁰ cm⁻³.

As described above, according to the third embodiment, similarly to the first embodiment, it is possible to realize a MOSFET capable of suppressing a decrease in breakdown voltage.

In the first to third embodiments, the case of 4H-SiC is described as an example of the crystal structure of SiC, but the present disclosure can also be applied to devices using SiC having other crystal structures such as 6H-SiC and 3C-SiC. In addition, it is also possible to apply a face other than the (0001) face to the surface of the silicon carbide layer 10.

In the first to third embodiments, the case where the first conductive type is an n-type and the second conductive type is a p-type is described as an example, but the first conductive type can be a p-type, and the second conductive type can be an n-type.

In the first to third embodiments, aluminum (Al) is exemplified as the p-type impurities, but boron (B) can also be used. In addition, nitrogen (N) and phosphorus (P) are exemplified as the n-type impurities, but arsenic (As), antimony (Sb), and the like can also be applied.

In the first to third embodiments, the case where the gate electrode 16 has a stripe shape in the device region 101 has been described as an example. However, for example, the gate electrode 16 may have a mesh shape.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a device region; and
a termination region surrounding the device region,
wherein the device region includes:
a first electrode;
a second electrode;
a silicon carbide layer provided between the first electrode and the second electrode and having a first face on a side of the first electrode and a second face on a side of the second electrode, the silicon carbide layer including:
a first silicon carbide region of a first conductive type including a first region and a second region provided between the first region and the first face;
a second silicon carbide region of a second conductive type provided between the second region and the first face and electrically connected to the first electrode;
a third silicon carbide region of a first conductive type provided between the second silicon carbide region and the first face and electrically connected to the first electrode; and
a fourth silicon carbide region of a second conductive type provided between the first region and the second region;
a gate electrode provided in the silicon carbide layer and facing the fourth silicon carbide region, the second region, the second silicon carbide region, and the third silicon carbide region; and
a gate insulating layer provided between the gate electrode and the silicon carbide layer,
the termination region includes:
the second electrode; and
the silicon carbide layer including:
the first silicon carbide region including the first region and the second region;
a fifth silicon carbide region of a second conductive type provided between the second region and the first face and electrically connected to the first electrode;
a plurality of sixth silicon carbide regions of a second conductive type provided between the second region and the first face, disposed in a first direction from the device region toward the termination region with respect to the fifth silicon carbide region, spaced apart from the fifth silicon carbide region, and spaced apart from each other in the first direction;
a seventh silicon carbide region of a second conductive type provided between the first region and the second region and electrically connected to the first electrode;
at least one eighth silicon carbide region of a second conductive type provided between the first region and the second region, disposed in the first direction with respect to the seventh silicon carbide region, and spaced apart from the seventh silicon carbide region; and
at least one ninth silicon carbide region of a second conductive type provided between the second region and the first face, disposed in the first direction with respect to the sixth silicon carbide region, and spaced apart from the sixth silicon carbide region,
wherein a first position of an end portion of the seventh silicon carbide region on a side opposite to the device region in the first direction is disposed closer to the device region than a second position of an end portion of the fifth silicon carbide region on a side opposite to the device region in the first direction,
a third position of an end portion of one of the at least one eighth silicon carbide region on a side opposite to the device region in the first direction, the one of the at least one eighth silicon carbide region being farthest from the device region in the first direction among the at least one eighth silicon carbide region, is disposed closer to the device region than a fourth position of an end portion of one of the sixth silicon carbide region on a side opposite to the device region in the first direction, the one of the sixth silicon carbide region being farthest from the device region in the first direction among the sixth silicon carbide regions, the third position being disposed farther from the device region in the first direction than a fifth position of an end portion of another one of the sixth silicon carbide regions on the side opposite to the device region in the first direction, the another one of the sixth silicon carbide regions being second farthest from the device region in the first direction among the sixth silicon carbide regions, and
a first distance between one of the at least one ninth silicon carbide region closest to the device region in the first direction among the at least one ninth silicon carbide region and the one of the sixth silicon carbide regions is less than a second distance between the one of the sixth silicon carbide region and the another one of the sixth silicon carbide regions.

2. The semiconductor device according to claim 1, wherein a first conductive type impurity concentration in the second region is higher than a first conductive type impurity concentration in the first region.

3. The semiconductor device according to claim 1, wherein the fifth silicon carbide region, the sixth silicon carbide regions, the seventh silicon carbide region, the at least one eighth silicon carbide region, and the at least one ninth silicon carbide region surround the device region.

4. The semiconductor device according to claim 1, wherein a second conductive type impurity concentration in the at least one eighth silicon carbide region is higher than a second conductive type impurity concentration in the sixth silicon carbide regions and a second conductive type impurity concentration in the at least one ninth silicon carbide region.

5. The semiconductor device according to claim 1, wherein three or more of the sixth silicon carbide regions are provided, and a distance between two adjacent sixth silicon carbide regions in the first direction increases toward the first direction.

6. The semiconductor device according to claim 1, wherein two or more of the at least one eighth silicon carbide region are provided.

7. The semiconductor device according to claim 1, wherein three or more of the at least one eighth silicon carbide region are provided, and a distance between two adjacent eighth silicon carbide regions in the first direction increases toward the first direction.

8. The semiconductor device according to claim 1, wherein two or more of the at least one ninth silicon carbide region are provided.

9. The semiconductor device according to claim 1, wherein three or more of the at least one ninth silicon carbide region are provided, and a distance between two adjacent ninth silicon carbide regions in the first direction increases toward the first direction.

10. The semiconductor device according to claim 1, wherein the second conductive type impurity concentration in the sixth silicon carbide regions is equal to a second conductive type impurity concentration in the fifth silicon carbide region or is higher than the second conductive type impurity concentration in the fifth silicon carbide region.

11. The semiconductor device according to claim 1, wherein the second conductive type impurity concentration in the at least one eighth silicon carbide region is lower than a second conductive type impurity concentration in the seventh silicon carbide region, and the second conductive type impurity concentration in the at least one eighth silicon carbide region is higher than the second conductive type impurity concentration in the sixth silicon carbide regions.

12. The semiconductor device according to claim 1, wherein the silicon carbide layer in the termination region further includes a tenth silicon carbide region in contact with the fifth silicon carbide region and the seventh silicon carbide region.

13. The semiconductor device according to claim 12, wherein the termination region further includes:
a conductive layer provided in the silicon carbide layer and facing the seventh silicon carbide region and the tenth silicon carbide region; and
an insulating layer provided between the conductive layer and the silicon carbide layer.
